(19) United States
(12) Patent Application Publication
(10) Pub. No.: US 2008/0060696 A1
(43) Pub. Date: Mar. 13, 2008

(54) Energy collecting system

(75) Inventors: Fang-Chuan Ho, Taoyuan Hsien (TW); Kung-Ueh Lin, Taoyuan Hsien (TW); Yang-Lin Chen, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/898,010

(22) Filed: Sep. 7, 2007

(30) Foreign Application Priority Data
Sep. 12, 2006 (TW) 95133592

(51) Int. Cl. H01L 31/052

(52) U.S. Cl. 136/246

(57) ABSTRACT

The invention discloses an energy collecting system comprising a substrate; a photosensitive layer selectively disposed on the substrate; and at least one convex lens disposed on the photosensitive layer. The shape of the convex lens is a semi-spheroid, thinner semi-spheroid, semi-columned, or thinner semi-columned shape. The convex lenses are arranged in an array order and are coated with an anti-reflection layer.

### BACKGROUND OF THE INVENTION

1. Field of the Invention

The present invention relates to an energy collecting system and in particular, to an energy collecting system which collects solar energy and is capable of enhancing the photoelectric conversion efficiency.

2. Description of the Related Art

A solar collector receives solar energy using photovoltaic cells and converts it to electricity. The photovoltaic cell can be a single-leveled or a multi-leveled structure.

In U.S. Pat. No. 6,399,874, a disclosed single-leveled square (7mm×7 mm) photovoltaic cell collects energy from the sunlight utilizing a Fresnel lens.

Higher photoelectric conversion efficiency can be achieved employing a solar cell with a multi-leveled structure. In U.S. Pat. No. 6,881,893, for example, a device disclosed employing a magnifying lens for focusing the light. The magnifying lens is disposed at the center of a circular plate which serves as a cover of a collection unit of the device. The light is collected in the funneled collection unit, wherein there is a photo sensor disposed at the bottom of the funneled collection unit.

In U.S. Pat. No. 6,700,054, a solar collector with a multi-leveled structure is disclosed. The solar collector is constructed as a funneled light receiver with a broad inlet. The incident light passes through the funneled wall, or reflects to the funneled wall then enters a soda-limed glass container with a convex top. There is mineral oil with a relatively high refractive index disposed in the soda-limed glass container. The glass container can reflect most of the light via the interface between the container wall and the mineral oil, and the leaked light can be reflected to enter the glass container by external reflectors. Accordingly, a light sensor at the bottom center of the glass container absorbs most of the light entering the collection device. The device, however, occupies a large space and takes time to be launched because of its large volume and complex structure.

In U.S. Pat. No. 6,061,181, a planar non-tracking light collector plate is disclosed. The light collector plate is configured with photovoltaic cell units, and includes lenses with large openings. The prism array of the light collector plate serves as a light path, guiding the light to photovoltaic cells. The light collector plate, however, is fragile and manufacture thereof is not easy.

Another planar solar panel disclosed in U.S. Pat. No. 6,528,716 has a simpler structure and better conversion efficiency.

Referring to the planar solar plate 100 shown in FIG. 1, a photovoltaic cell layer 102 and the reflection mirror 103 are on the substrate 101. The area the photovoltaic cells occupy is reduced due to the existence of the reflection mirror. Conversion efficiency of sunlight, however, may degrade because incident angle of sunlight is limited to reflection surfaces of adjacent tilted reflection mirrors.

Accordingly, an energy collecting system capable of solving the above described problems is desirable.

### BRIEF SUMMARY OF THE INVENTION

One embodiment of an energy collecting system of the present invention includes a substrate; a photosensitive layer selectively disposed on the substrate; and at least a convex lens disposed on the photosensitive layer. The convex lens has semi-spheroid, thinner semi-spheroid, semi-columned or thinner semi-columned shape. The convex lenses are arranged in an array over the substrate, and are coated with an antireflection layer. Sunlight can be focused onto the photosensitive layer via refraction from the convex lens. Accordingly, sunlight can reach the photosensitive layer through a simplified refraction path, optimizing collection of solar energy.

In another embodiment, a surface of the convex lens further includes at least one protrusion.

In another embodiment, the convex lens is single-layered and made of glass or plastic.

In another embodiment, the convex lens includes a plurality of layers made of the same or of different materials. The materials can be glass, plastic, mineral oil, gel, water, gas, or vacuum.

In order to make the photosensitive layer effectively capture sunlight at various incident angles during the daytime, an optical interface is disposed between the convex lens and the photosensitive layer. The optical interface, for example, is consisted of a material that has a refraction index which changes gradually. Alternatively, the optical interface can be a multi-layered film which has a refraction index which changes gradually. The multi-layered film is a dielectric material and has a refraction index larger than 2.1. The multi-layered film, for example, can be TiO₂, Nb₂O₃, or ZrO₂. Alternatively, to gradually change the refraction index, one layer of the film adjacent to the convex lens has a refraction index between those of the convex lens and the other layers.

The photosensitive layer of the disclosed energy collecting system is not limited to the conventional photovoltaic cell. Alternatively, it can be a photothermal converter or a combination of the photovoltaic cell and the photothermal converter.

### BRIEF DESCRIPTION OF THE DRAWINGS

The invention will become more fully understood from the subsequent detailed description and the accompanying drawings, which are given by way of illustration only, and thus are not limitative of the present invention, and wherein:

FIG. 1 is a schematic view showing a conventional photovoltaic cell;

FIG. 2 is a schematic view showing an embodiment of the energy collecting system according to the present invention;

FIG. 3 is cross-sectional view of one convex lens along the X-X′ line shown in FIG. 2;

FIGS. 4A and 4B are respective schematic views showing light arriving at the photosensitive layer through the convex lens and not through the convex lens;

FIGS. 5A and 5B are perspective views showing light entering the semi-spheroid convex lens and semi-columned convex lens;

FIG. 6 is a perspective view showing the change of the luminous flux for a thinner semi-columned convex lens over the photosensitive layer;

FIG. 7 is cross-sectional view showing parallel light passing through a single convex lens;

FIGS. 8A, 8B, and 8C are reflection spectrums of optical interfaces in various film compositions;

FIGS. 9A and 9B are respective cross-sectional view of another embodiment of the energy collecting system according to the invention;

FIG. 10 is a cross-sectional view of another embodiment of the energy collecting system according to the invention; and.

FIG. 11 is a schematic view showing the distance between adjacent convex lenses.

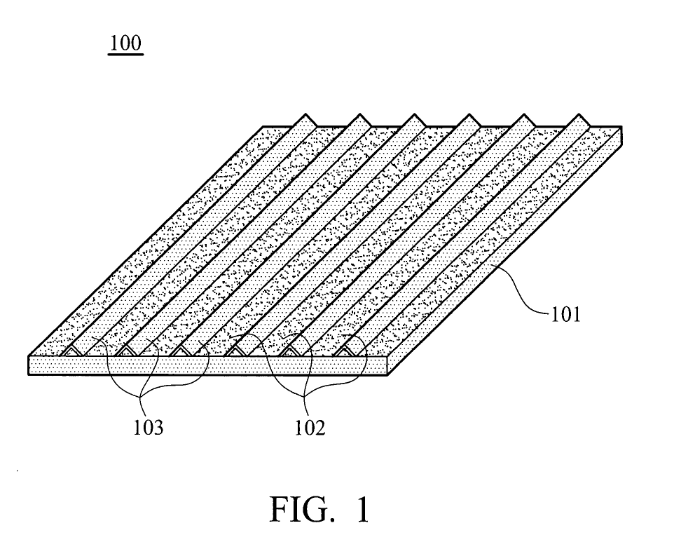

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

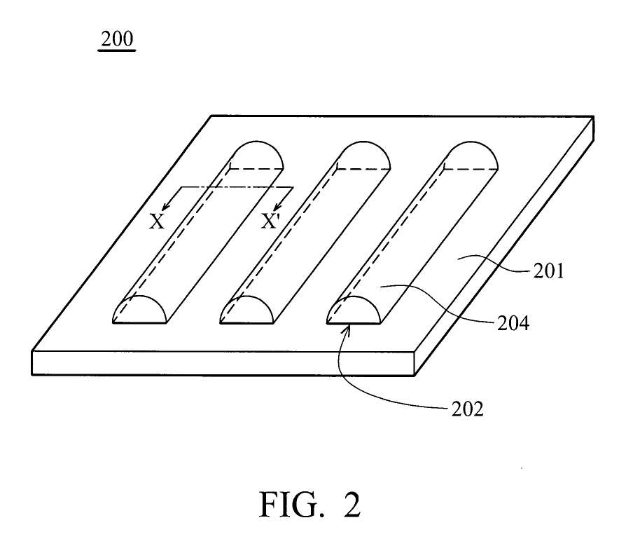

FIG. 2 is a schematic view showing an embodiment of the energy collecting system according to the present invention. An energy collecting system 200 includes a substrate 201, a photosensitive layer 202 and a plurality of convex lenses 204. The photosensitive layer 202 is disposed on the substrate 201, and the convex lenses 204 are on the photosensitive layer 202. In this embodiment, the photosensitive layer 202 is selectively disposed on the substrate 201. Note that the photosensitive layer 202 does not have to be disposed all over the substrate 201; more specifically, the pertinent aspect is that the photosensitive layer 202 is between the convex lenses 204 and the substrate 201. In this embodiment, the convex lenses 204 are semi-columned (also called semi-cylindrical) and are arranged in an array. Alternatively, the convex lenses 204 can be semi-spheroid, thinner semi-spheroid, thinner spheroid, thinner columned, or thinner semi-columned shape.

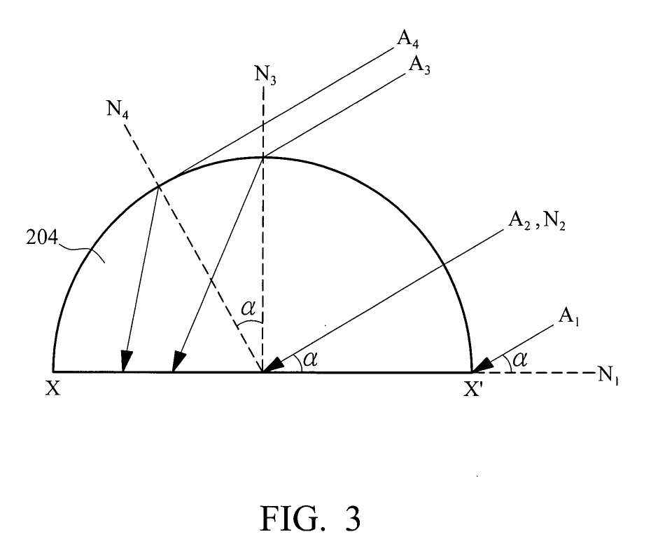

FIG. 3 is a cross-sectional view along the X-X′ line of one convex lens 204 shown in FIG. 2. It is noted that whether the convex lens is semi-columned or semi-spheroid, a cross section thereof is semi-spheroid as shown in FIG. 3. In FIG. 3, the incident angle a of the light refers to the angle of the incident path to the bottom of the convex lens. A₁, A₂, A₃, A₄ respectively refer to various parallel light paths, and N₁, N₂, N₃, N₄ respectively refer to normal lines formed at cross points between the light paths A₁, A₂, A₃, A₄ and the convex lens surface. Accordingly, as shown in FIG. 3, The light paths A₁, A₂, A₃, A₄ have respective incident angles relative to the convex lens surface, such as α, 0°, (90°−α) and 90°.

Materials used to form the convex lens can be glass or plastic, and refraction index thereof is larger than that of air. The light striking upon the convex lens surface arrives at the photosensitive layer underlying the convex lens through the convex. During the daytime, the incident angle a relative to the photosensitive layer is between 0° and 180°.

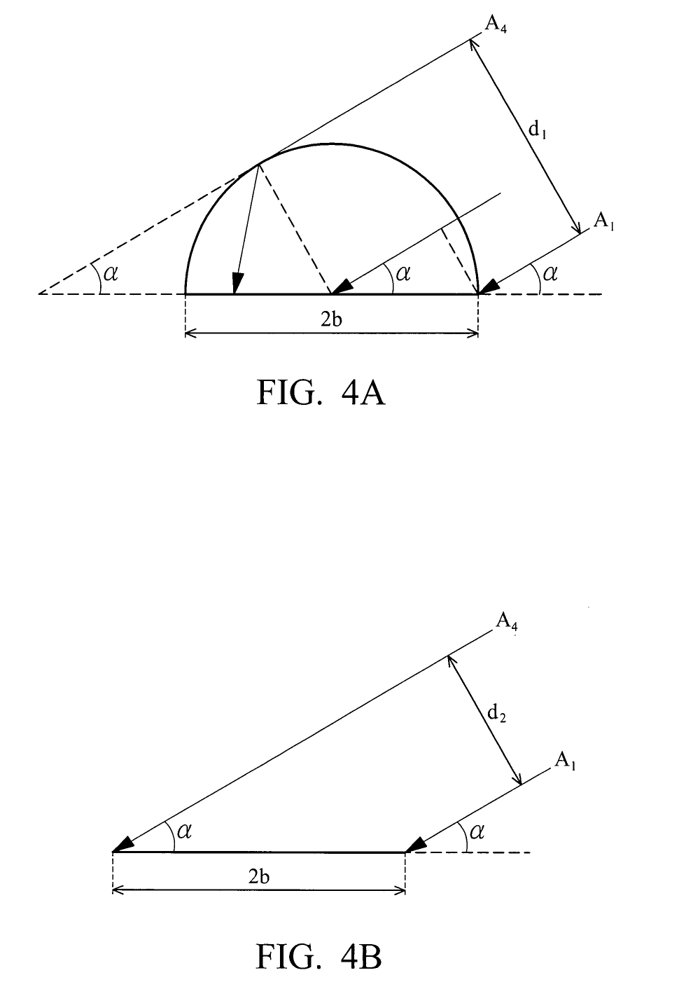

FIGS. 4A and 4B are respective schematic views showing light arriving at the photosensitive layer through the convex lens and not through the convex lens when the photosensitive layers have the same thicknesses. In FIG. 4A, the width of the convex lens bottom is 2b identical to the width of the photosensitive layer shown in FIG. 4B. When the incident angle is α, d₁ represents the width of an area on the photosensitive layer where light passing through the convex lens strikes, and d₂ represents the width of an area on the photosensitive layer where light directly strikes without passing through the convex lens. The widths satisfy the following formulas:

d₁=b (1+sin α); and

d₂=2b sin α;

when α=90°, then d₁=d₂; and

when α≠#90°, then d₁>d₂.

Compared to the photosensitive layer without a convex lens, it is deduced from the formulas above, that the photosensitive layer of the embodiment has more luminous flux via the convex lens during the daytime.

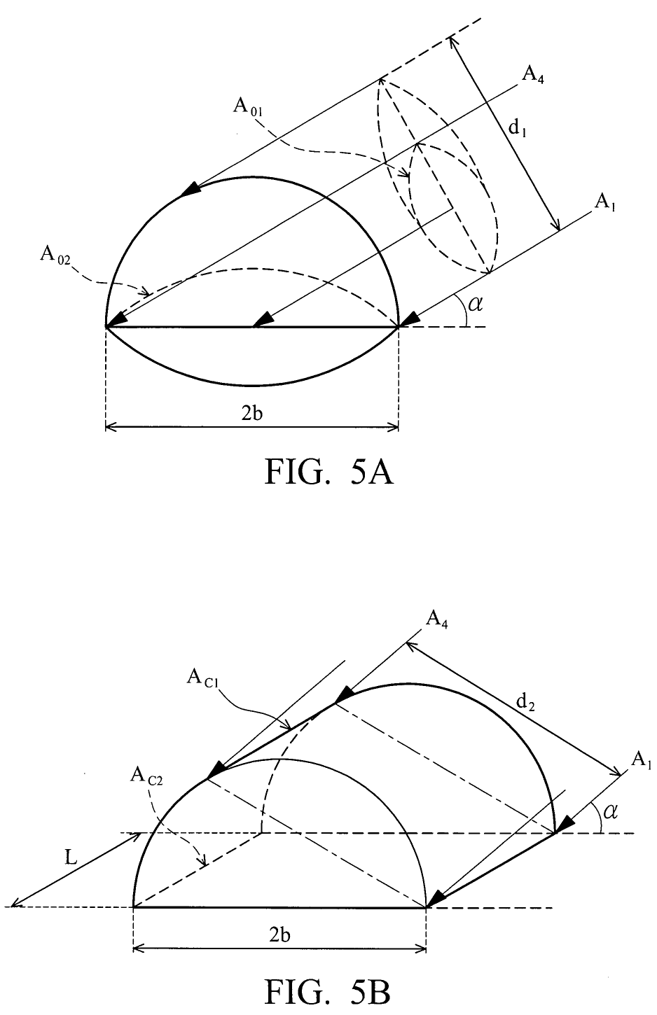

FIGS. 5A and 5B are perspective views showing light with an incident angle α entering the semi-spheroid convex lens and semi-columned convex lens.

As shown in FIG. 5A, the light strikes the semi-spheroid convex lens, and a projection area A₀₁ thereof is obtained. The projection area A₀₁ is a combination of a semicircle with a radius b and a semiellipse with a long axis b and a short axis b(sin α). Accordingly, the length of d₁ is b(1+sin α). In FIG. 5B, when d₂ equals b(1+sin α), a projection area A_{c1} of the semi-columned convex lens equals d₂L. In FIG. 5B, 2b refers to the diameter of the semi-columned circle, and L refers to the length of the semi-columned convex lens. Accordingly, when the incident angle, referenced to a normal line from earth, of sunlight is between −90° and 90°, the luminous flux at the photosensitive layer at the bottom of the semi-spherical convex lens is a sum of all sectional areas.

Identically, for the photosensitive layer without a semi-spherical or semi-columned convex lens thereon, the area formula from sunlight is A₀₂=πb²sinα and A_{c2}=2bLsinα, respectively.

As described, when comparing the photosensitive layer covered with a semi-spherical convex lens and the photosensitive layer not covered with a semi-spherical convex lens thereon, the difference of total luminous flux at the photosensitive layer is represented as the following formula:

$$\begin{matrix}{ρ}_{0} = \frac{{ɛ}_{01} - {ɛ}_{02}}{{ɛ}_{02}} \\ = \frac{2 {\int }_{0}^{π / 2} ( {A}_{01} - {A}_{02} ) d α}{2 {\int }_{0}^{π / 2} {A}_{02} d α} \\ = \frac{π {b}^{2} ( π / 2 - 1 )}{2 π {b}^{2}} \\ = \frac{1}{2} ( \frac{π}{2} - 1 )\end{matrix}$$

wherein A₀₁=πb²(1+sin α)/2; and

A₀₂=πb² sin α.

Alternatively, when comparing the photosensitive layer covered with a semi-spherical convex lens and the photosensitive layer not covered with a semi-spherical convex lens thereon, the difference of total luminous flux at the photosensitive layer is represented as the following formula:

$$\begin{matrix}{ρ}_{c} = \frac{{ɛ}_{c 1} - {ɛ}_{c 2}}{{ɛ}_{c 2}} \\ = \frac{2 {\int }_{0}^{π / 2} ( {A}_{c 1} - {A}_{c 2} ) d α}{2 {\int }_{0}^{π / 2} {A}_{c 2} d α} \\ = \frac{b L ( π / 2 - 1 )}{2 b L} \\ = \frac{1}{2} ( \frac{π}{2} - 1 )\end{matrix}$$

wherein, A_{c1}=Lb(1+sin α); and

A_{c2}=2Lb sin α.

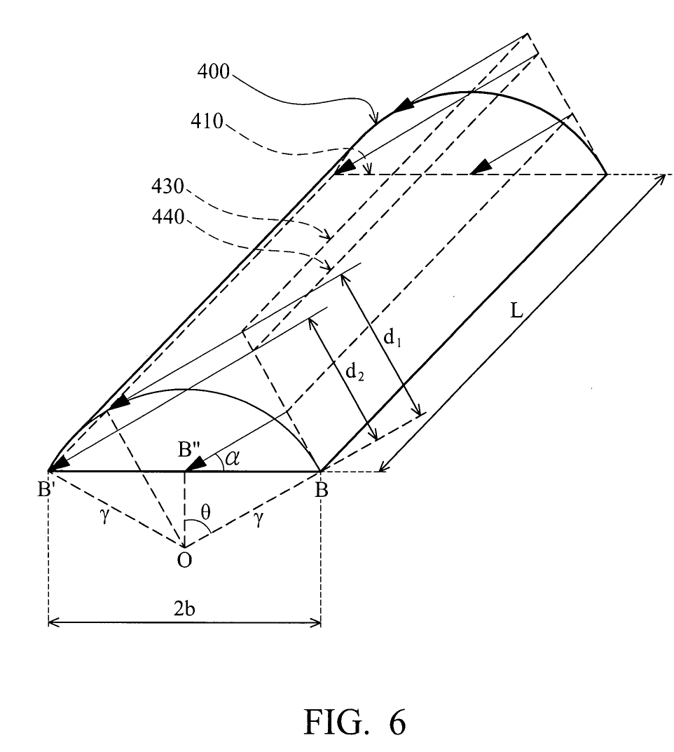

FIG. 6 is a perspective view showing the change of the luminous flux for a thinner semi-columned convex lens 400 over the photosensitive layer. In the specification, the focal point of the semi-columned convex lens is below the bottom of the convex lens. In FIG. 6, the bottom area of the thinner semi-columned convex lens equals to length L multiplied by width 2b. O represents the center of the circle constructed by circular arc BB′, and r represents the radius. Line BB′ has a length 2b and a central point B″. Accordingly, the rectangular area 2bL of the thinner semi-columned convex lens 400 equals to the area of the photosensitive layer 410. Rectangular cross sections 430 and 440 respectively have widths d₁ and d₂. That is, the incident surface area 430 is d₁L when parallel light strikes through the thinner semi-columned convex lens 400, and the incident surface area 440 is d₂L when parallel light does not strike through the thinner semi-column convex lens 400. Accordingly, the difference of total luminous flux at the photosensitive layer is represented as the following formula:

$$\begin{matrix}{ρ}_{e} = \frac{{ɛ}_{e 1} - {ɛ}_{e 2}}{{ɛ}_{e 2}} \\ = \frac{2 {\int }_{0}^{π / 2} ( {A}_{e 1} - {A}_{e 2} ) d α}{2 {\int }_{0}^{π / 2} {A}_{e 2} d α} \\ = \frac{2 r L ( θ - sin θ )}{4 r L sin θ} \\ = \frac{( θ - sin θ )}{2 sin θ}\end{matrix}$$

wherein, A_{c1}={r[1−cos(θ−α)]+2r sin θ sin α}L; and

A_{c2}=L(2r sin θ)sin α.

Aₑ₁ is the projection area with a thinner columned convex lens, and Aₑ₂ is the projection area without a thinner columned convex lens.

Comparing examples with and without convex lens, the luminous flux received by the photosensitive layer for examples with convex lens is more. When the incident angle is less than 180°, enhancement of the photosensitive layer was seen, as presented in the following table.

| angle θ at the centre of the | |
|---|---|
| thinner column | Efficiency enhanced |
| (Unit: degree) | (%) |
| 10 | 0.25 |
| 20 | 1.03 |
| 30 | 2.36 |
| 40 | 4.31 |
| 50 | 6.96 |
| 60 | 10.46 |
| 70 | 15.01 |
| 80 | 20.89 |
| 90 | 28.54 |

This table shows the efficiency enhanced at different angle θ when the photosensitive layer is covered with the convex lens. θ refers to angle from the centre of the thinner columned convex lens. When θ is 90°, the thinner columned convex lens is a semi-spheroid lens, thus the efficiency enhanced is highest.

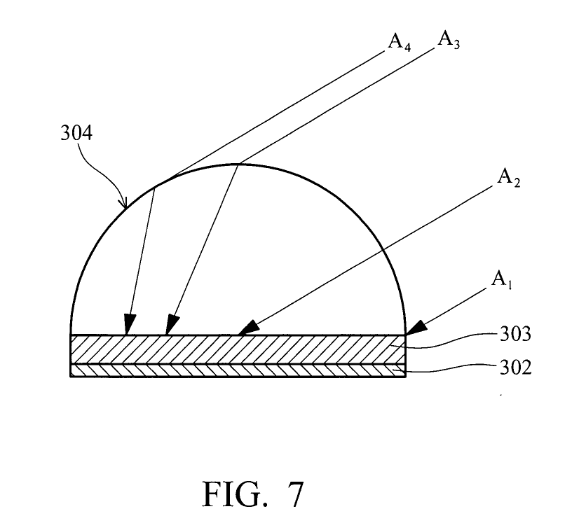

Another embodiment is described below according to FIG. 7. FIG. 7 is a cross-sectional view showing parallel light A₁, A₂, A₃, A₄ passing through a single convex lens 304. In FIG. 7, the main difference with FIG. 3 is that the surface of the convex lens 304 is coated with an anti-reflection layer, and an optical interface 303 is further disposed between the convex lens 304 and the photosensitive layer 302. That is, parallel light A₁, A₂, A₃, A₄ passes through the convex lens 304 and the optical interface 303 before arriving at the photosensitive layer 302.

The optical interface 303 can be constructed by an air containing layer and at least one film, such as air, silicon nitride, TiO₂, or a combination thereof.

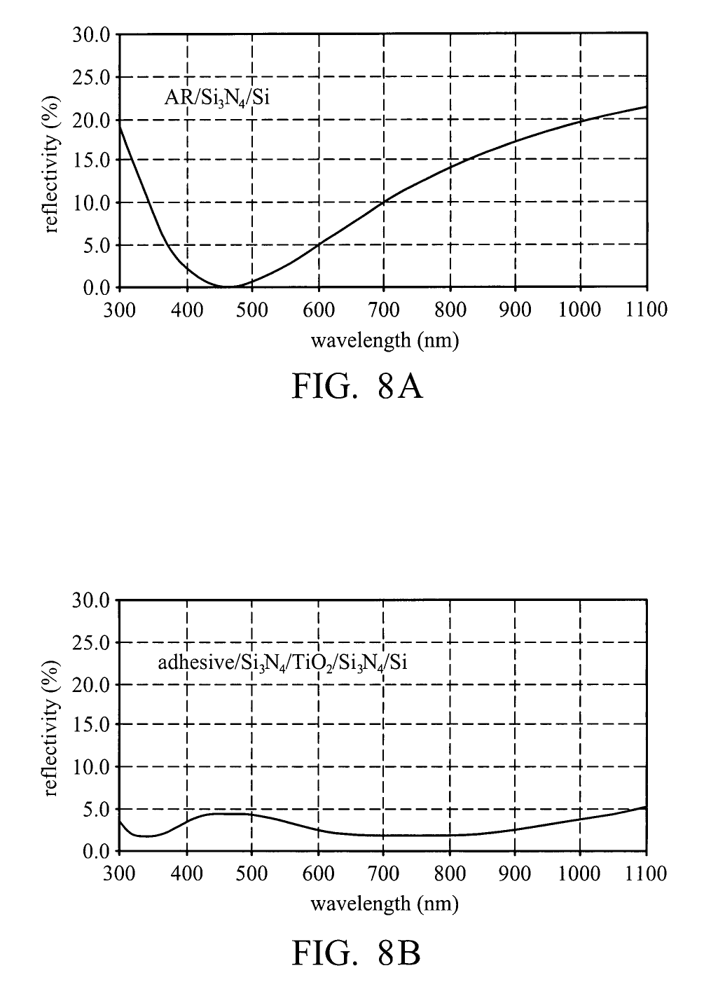

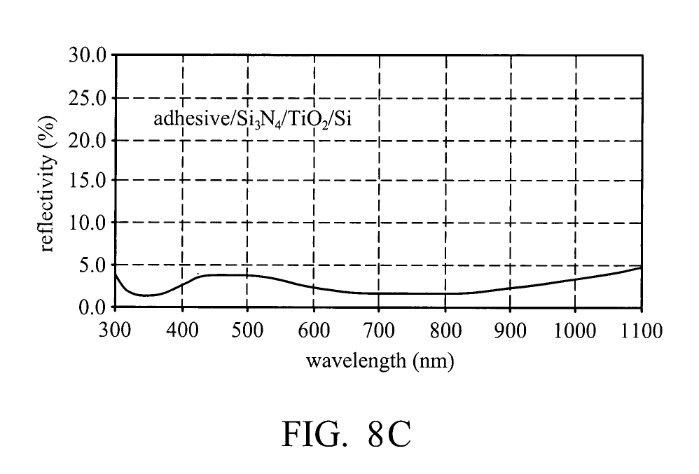

FIGS. 8A to 8C are reflection spectrums of optical interfaces of various film compositions. In FIGS. 8A to 8C, the optical interface is disposed on the photosensitive layer of polysilicon, and the convex lens thereon has a refraction index of 1.52. In FIG. 8A, the optical interface is constructed of air and silicon nitride; in FIG. 8B, the optical interface is constructed of adhesive, silicon nitride, TiO₂ and silicon nitride; and in FIG. 8C, the optical interface is constructed of adhesive, silicon nitride and TiO₂. For the optical interface composed of a three-layered film, if the photosensitive layer 302 is polysilicon photovoltaic cell, the layer adjacent to the photovoltaic cell can be a silicon nitride layer. The silicon nitride layer assists in preventing dangling bonds from generating in the polysilicon photovoltaic cell. Accordingly, the silicon nitride layer can stabilize the hydrogen bonds on the surface of the polysilicon photovoltaic cell. In this embodiment, the silicon nitride layer may have a thickness of 10 nm.

Because the incident light passes through the optical interface before arriving at the photosensitive layer, energy conversion efficiency in photosensitive layer can be enhanced. Additionally, energy conversion efficiency can increase 33% if the photosensitive layer is a photovoltaic cell, and the convex lens is plastic.

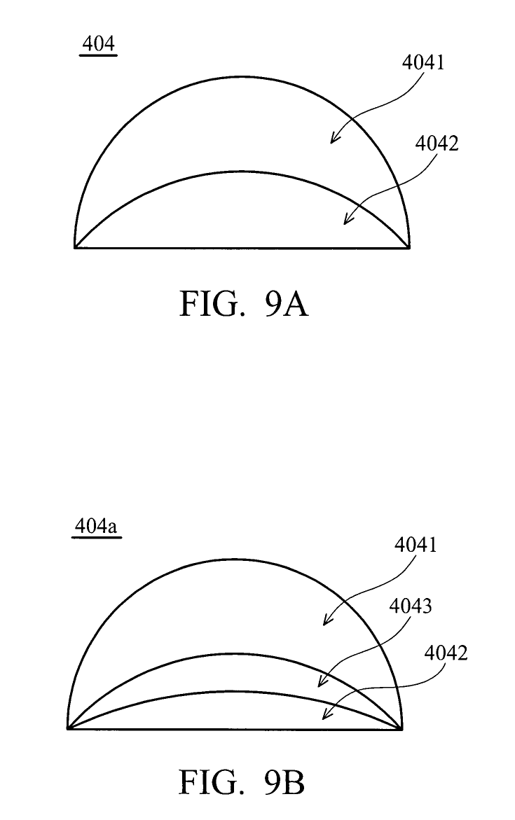

FIGS. 9A and 9B are respective cross-sectional views of the other embodiments of convex lenses 404 and 404a, respectively. Compared to FIG. 3, the convex lens 404 can be constructed with at least two materials. As shown in FIG. 9A, if the layer 4041 is glass, the other layer of the convex lens 404 can be other materials such as glass, plastic, mineral oil, gel, water, gas, or vacuum. As shown in FIG. 9A, the layers 4041 and 4042 are of different materials, and can be glass, plastic, mineral oil, gel, water, gas, or vacuum. The convex lens 404 can be semi-columned or semi-spheroid lenses. In this embodiment, the photosensitive layer 202, such as a photovoltaic cell or a photothermal converter, is disposed underlying the convex lens 404 or 404a and is arranged on the substrate in an array.

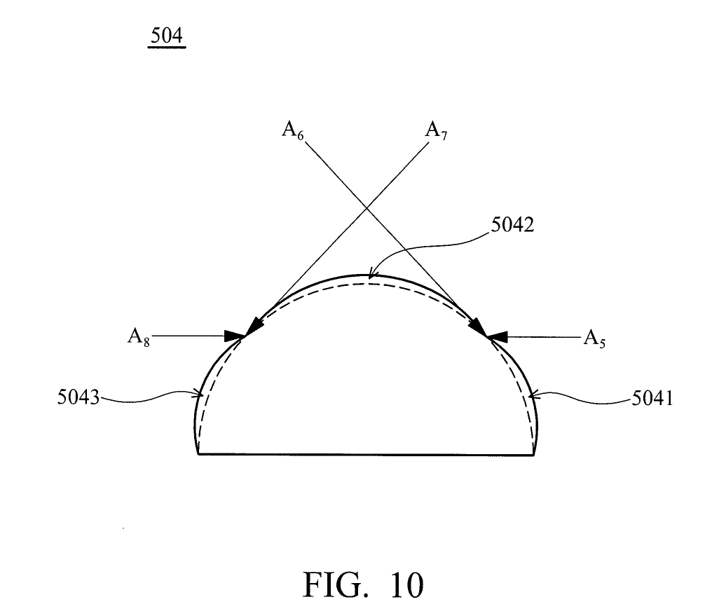

FIG. 10 is a cross section of still another embodiment of a convex lens. In this embodiment, the convex lens may include a plurality of convexities. As shown in FIG. 10, the convex lens 504 possesses protrusions 5041, 5042 and 5043 on the surface thereof. In this embodiment, the protrusions 5041, 5042 and 5043 may serve as subspherical lenses. As to the protrusion 5042, the effective range of the incident angle is between the light path A₅ and the light path A₈. As to the protrusion 5041, the effective range of the incident angle is between the light paths A₅ and A₆. As to the protrusion 5043, the effective range of the incident angle is between the light paths A₇ and A₈. The protrusions can increase the luminous flux entering the convex lens 504.

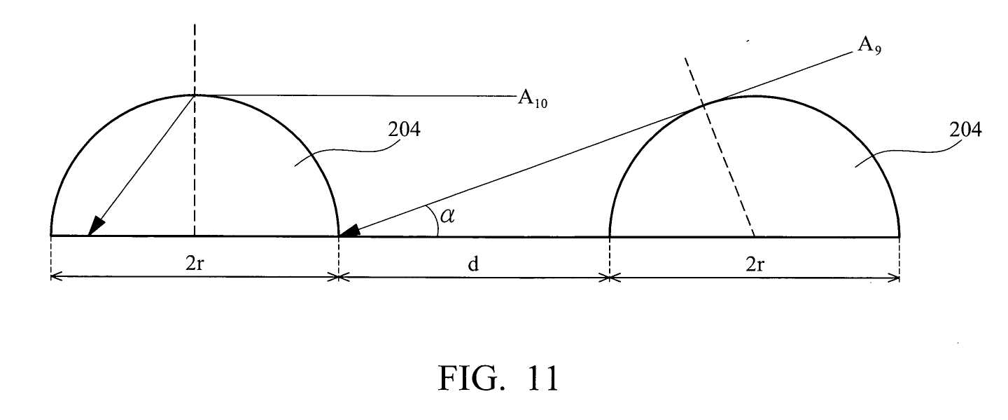

FIG. 11 is a schematic view showing the minimum distance between two adjacent convex lenses, such as semi-columned lenses 204 or semi-spheroid lenses, which are disposed on the substrate in an array. In FIG. 11, the diameter of a circle formed by a section of the convex lens is 2r, and the distance between two adjacent convex lenses 204 on the substrate is d. To maximize the luminous flux of respective lenses, the light path such as A₉ shown in FIG. 11 should not be blocked by the adjacent convex lens. The light path A₉ has an incident angle a equal to tan⁻¹(r/(r+d)). In this embodiment, blocking of the light path by the two adjacent convex lenses can be avoided if the distance d between two adjacent convex lenses is increased enough; in doing so, however, total area of the energy collection system increases. Accordingly, the distance d between adjacent convex lenses depends on requirements (or need).

In the energy collection system for these embodiments of the invention, an optical interface is further disposed between the convex lens and the photosensitive layer, thus energy collection efficiency can be effectively enhanced. As a result, with the same conversion efficiency of electrical energy or thermal energy when compared to conventional energy collecting systems, embodiments of the invention reduce total area of the photosensitive layer, thus reducing costs. Meanwhile, compared to conventional energy collecting systems utilizing photovoltaic cells, the embodiments of the invention are simpler, leading to reduction of manufacture costs.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An energy collecting system comprising
a substrate;
a photosensitive layer selectively disposed on the substrate; and
at least a convex lens disposed on the photosensitive layer.

2. The energy collecting system as claimed in claim 1, wherein the convex lens has a semi-spheroid, thinner semi-spheroid, semi-columned or thinner semi-columned shape.

3. The energy collecting system as claimed in claim 2, wherein the photosensitive layer includes a polysilicon photovoltaic cell, photothermal converter, or a combination thereof.

4. The energy collecting system as claimed in claim 3, wherein the convex lenses are arranged in an array.

5. The energy collecting system as claimed in claim 3, further comprising an optical interface between the convex lens and the photosensitive layer.

6. The energy collecting system as claimed in claim 5, wherein the optical interface comprises a material with a gradually changed refraction index.

7. The energy collecting system as claimed in claim 5, wherein the optical interface includes at least one thin film.

8. The energy collecting system as claimed in claim 7, wherein the thin film includes air, adhesive, silicon nitride, titanium dioxide, or a combination thereof.

9. The energy collecting system as claimed in claim 7, wherein the thin film includes a dielectric material.

10. The energy collecting system as claimed in claim 9, wherein the dielectric material has a refraction index larger than 2.1.

11. The energy collecting system as claimed in claim 10, wherein the dielectric material includes TiO₂, Nb₂O₃, or ZrO₂.

12. The energy collecting system as claimed in claim 10, wherein the thin film adjacent to the convex lens has a refraction index between that of the convex lens and that of other thin films.

13. The energy collecting system as claimed in claim 10, further comprising a silicon nitride film between the optical interface and the photosensitive layer.

14. The energy collecting system as claimed in claim 13, wherein the silicon nitride film has a thickness of 10 nm.

15. The energy collecting system as claimed in claim 1, wherein the convex lens is coated with an anti-reflection layer.

16. The energy collecting system as claimed in claim 1, wherein a surface of the convex lens further includes at least one protrusion.

17. The energy collecting system as claimed in claim 16, wherein the protrusion is a subspherical lens.

18. The energy collecting system as claimed in claim 1, wherein the convex lens is a single layer and includes glass or plastic.

19. The energy collecting system as claimed in claim 1, wherein the convex lens includes a plurality of layers made of same or different materials.

20. The energy collecting system as claimed in claim 19, wherein the plurality of layers are formed by glass, plastic, mineral oil, gel, water, gas, or vacuum.
